(19) United States
(12) Patent Application Publication
(10) Pub. No.: US 2012/0127691 A1
(43) Pub. Date: May 24, 2012

(54) CONTROL APPARATUS

(75) Inventor: Yoshitaka OHFUCHI, Fukuoka (JP)

(73) Assignee: KABUSHIKI KAISHA YASKAWA DENKI, Kitakyushu-shi (JP)

(21) Appl. No.: 13/238,530

(22) Filed: Sep. 21, 2011

(30) Foreign Application Priority Data
Nov. 19, 2010 (JP) 2010-259285

(51) Int. Cl. H05K 7/00; H05K 13/00

(52) U.S. Cl. 361/827; 29/592.1

(57) ABSTRACT

A control apparatus includes a casing; an internal device accommodated in the casing and having a connection port to be connected to a cable; a frame on which the cable is distributed, the frame having an opening large enough for an operator to connect an end of the cable to the connection port through the opening; and a joining part joining the casing and the frame.

### CROSS-REFERENCE TO RELATED APPLICATIONS

The present application claims priority under 35 U.S.C. §119 to Japanese Patent Application No. 2010-259285 filed Nov. 19, 2010. The contents of this application are incorporated herein by reference in their entirety.

### BACKGROUND OF THE INVENTION

1. Field of the Invention

The present invention relates to a control apparatus.

2. Description of the Related Art

For example, International Publication No. 2007/122903 describes a control apparatus for industrial robots accommodating a plurality of internal devices.

In general, internal devices accommodated in the control apparatus are connected to cables. Part of the cables connected to the internal devices are bound together and distributed. The wiring route of the cables are usually not described in detail in the drawings. Therefore, in some cases, the assembler of the control apparatus connects the cables at the assembly site on the basis of his/her own skills.

### SUMMARY OF THE INVENTION

The control apparatus according to an embodiment of the present invention includes a casing; an internal device accommodated in the casing and having a connection port to be connected to a cable; a frame on which the cable is distributed, the frame having an opening large enough for an operator to connect an end of the cable to the connection port through the opening; and a joining part joining the casing and the frame.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a front view (with the door opened) of a robot control apparatus according to an embodiment of the present invention;

FIG. 2A is a schematic view of a frame of the robot control apparatus;

FIG. 2B is a schematic view of the frame of the robot control apparatus with cables distributed thereon;

FIG. 3 is a schematic view of a joining part of the robot control apparatus; and

FIG. 4 is an assembly diagram of the robot control apparatus.

### DESCRIPTION OF THE EMBODIMENTS

Embodiments of the present invention will be described below with reference to the accompanying drawings. In each drawing, components that are not relevant to the descriptions may be omitted.

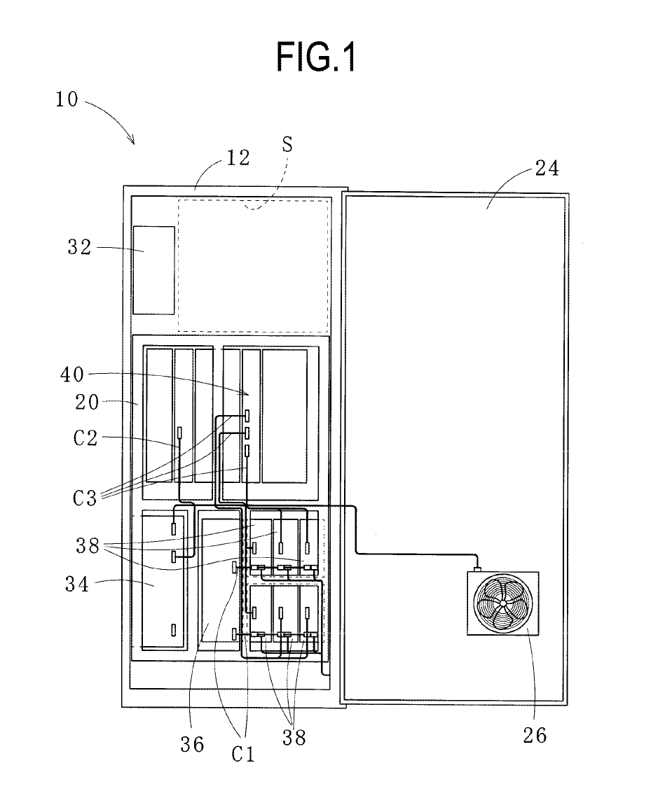

As illustrated in FIG. 1, a robot control apparatus (an example of a control apparatus) 10 according to an embodiment of the present invention includes a casing 12, a frame 20, and joining parts that connect the casing 12 and the frame 20. The robot control apparatus 10 controls the operation of, for example, a six-axis articulated robot (not shown).

The casing 12 is rectangular and has a width, depth, and height between, for example, 400 to 500 mm, 400 to 500 mm, and 1000 to 1500 mm, respectively. The front surface of the casing 12 has a door 24, which opens and closes. The door 24 has an exhaust fan 26 that discharges the air inside the casing 12.

The casing 12 accommodates internal devices, such as a wiring breaker 32, a power-supply unit 34, an AC-DC converter 36, servo amplifiers 38, and a CPU unit 40.

The primary side of the wiring breaker 32 is connected to an external power supply of the robot control apparatus 10 so that, when short-circuiting, etc. occurs on the secondary side, the wires are protected and the power supply is disconnected.

The power-supply unit 34 is connected to the secondary side of the wiring breaker 32 via a cable (not shown) and controls the ON/OFF of the power supply.

The AC-DC converter 36 is connected to the output side of the power-supply unit 34 via a cable (not shown) and converts the AC output voltage of the power-supply unit 34 to a predetermined DC voltage.

The servo amplifiers 38 drive servo motors (not shown), which move the joining parts of an articulated robot. In this embodiment, six servo amplifiers 38 are provided to drive the servo motors of a six-axis articulated robot. Connectors and terminal blocks (example of connection ports) are provided on the front surface of each servo amplifier 38.

Power is supplied from the AC-DC converter 36 to the servo amplifiers 38 via cables C1.

The CPU unit 40 controls the power-supply unit 34 and the servo amplifiers 38. Connectors and terminal blocks (example of connection ports) are provided on the front surface of the CPU unit 40.

Power is supplied from the AC-DC converter 36 to the CPU unit 40 via a cable (not shown). The CPU unit 40 and the power-supply unit 34 are connected via a cable C2. The CPU unit 40 and the servo amplifiers 38 are connected via cables C3.

In this way, the internal devices of the robot control apparatus 10 are connected to many cables.

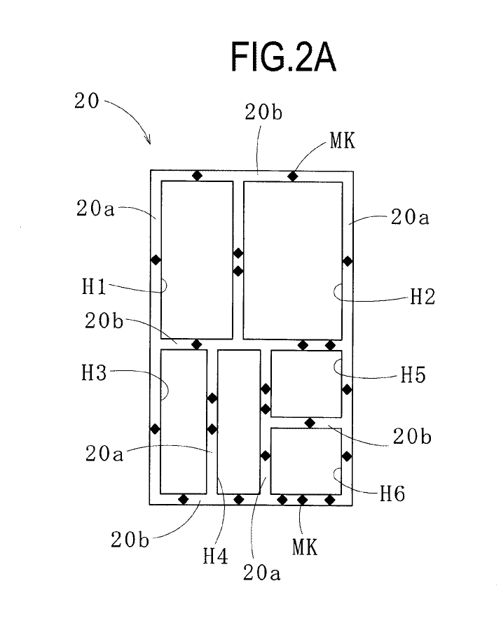

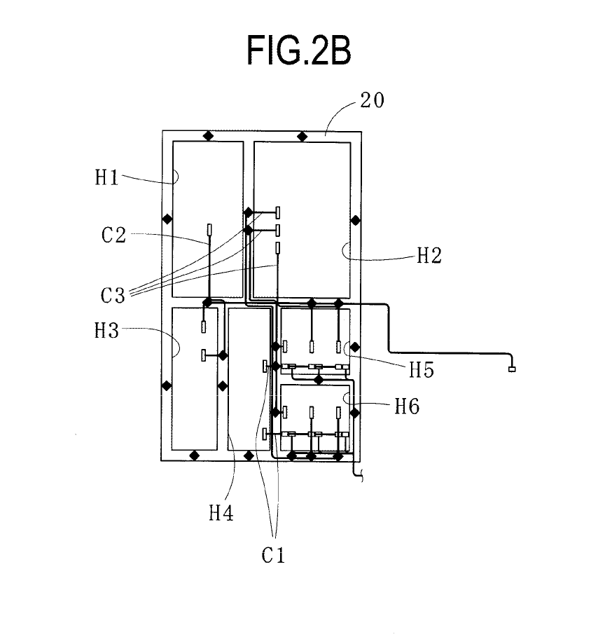

For example, as illustrated in FIG. 2A, the frame 20 is constituted of longitudinal members 20a and transverse members 20b joined together; the longitudinal members 20a have spaces on the left and right sides and are positioned such that the longitudinal direction substantially matches the vertical direction, and the transverse members 20b have spaces on the top and bottom sides and are positioned such that the longitudinal direction substantially matches the horizontal direction. The longitudinal members 20a and the transverse members 20b of the frame 20 define rectangular openings H1 to H6. As illustrated in FIG. 1, the longitudinal members 20a and the transverse members 20b of the frame 20 surround the connectors of the internal devices, when viewed from the front. The connectors of the internal devices are disposed toward the back of the openings H1 to H6.

When viewed from the side, the frame 20 is, for example, interposed between the internal devices and the closed door 24 (i.e., the frame 20 is disposed forward of the internal devices).

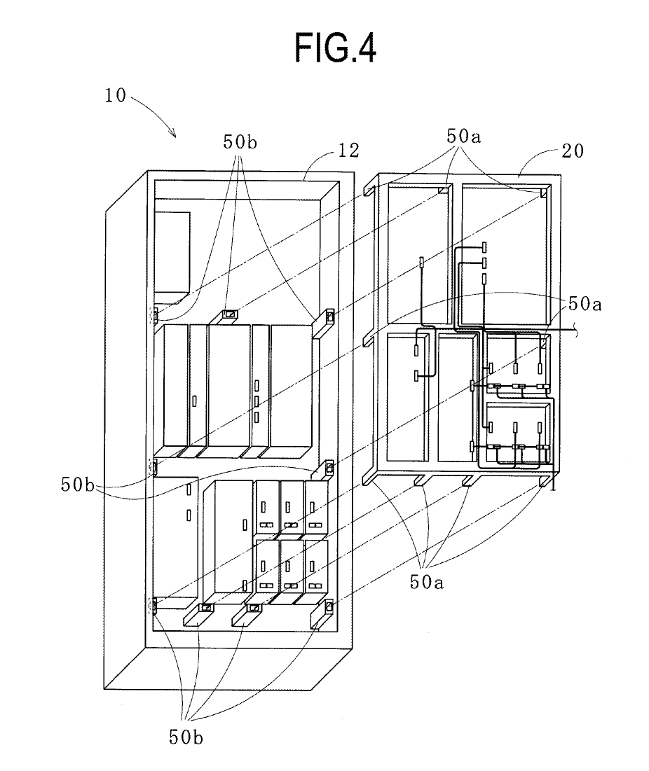

For example, as illustrated in FIG. 2A, rhombic marks MK are applied to the front surface of the frame 20. Each of the marks MK may be a number, a character, a symbol, etc. Each of the mark MK may instead be a combination of at least two of a figure, a number, a character, a symbol, etc. The marks MK are omitted in FIGS. 1 and 4.

As illustrated in FIGS. 1 and 2B, cables are distributed along the longitudinal members 20a and the transverse members 20b on the front surface of the frame 20 (on the side opposite to that facing the internal devices). By distributing the cables on the front surface of the frame 20, maintenance, such as cable replacement, is facilitated. The ends of the cables are passed through the openings H1 to H6 from the front surface of the frame 20 and are connected to the internal devices disposed toward the back of the frame 20. For example, the control cables C3 connecting the CPU unit 40 and the servo amplifiers 38 are distributed along the longitudinal members 20a and the transverse members 20b on the front surface of the frame 20. The connectors at one of the ends of the cables C3 are passed through the opening H2 and connected to connectors of the CPU unit 40. The connectors at the other ends of the cables C3 are passed through openings H5 and H6 and connected to connectors of the servo amplifiers 38.

Cable ducts may be formed on the front surfaces of the longitudinal members 20a and the transverse members 20b of the frame 20, and cables may be lead through the cable ducts.

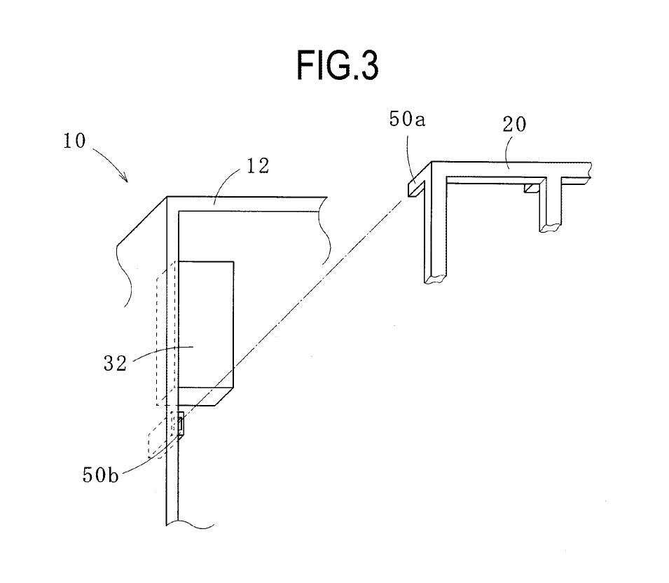

The joining parts join the frame 20 and the casing 12. As illustrated in FIG. 3, each joining part is constituted of at least a joining member 50a that are disposed on the frame 20 and protrudes toward the back and a joined member 50b that is disposed on the casing 12 and is depressed to receive the corresponding joining member 50a.

Space S defined by a dotted line in FIG. 1 is space reserved for devices that drive optional devices (external shafts), such as a positioner.

Next, a method of assembling (producing) the robot control apparatus 10 will be described. The robot control apparatus 10 is assembled in the following steps.

### Step 1

An operator secures the internal devices inside the casing 12.

### Step 2

The operator distributes the cables along a predetermined route on the frame 20 (see FIG. 2B).

The operator can use the marks MK, which are applied to the surface of the frame 20 on which the cables are distributed, as guides of the wiring route. The positions of the marks MK may indicate positions where the cables distributed on the frame 20 are introduced from the frame 20 to the openings H1 to H6. If operators use the marks MK as wiring route guides, differences in the wiring route can be reduced.

Steps 1 and 2 may be carried out in any order.

### Step 3

As illustrated in FIG. 4, the operator inserts the joining members 50a of the frame 20 on which the cables are distributed into the joined members 50b of the casing 12 to join the frame 20 and the casing 12.

### Step 4

The operator connected the cable ends to the internal devices. For example, the operator connects one end of the cable C2 (see FIGS. 1 and 2B) to the connector of the CPU unit 40 through the opening H1 and connects the other end to the connector of the power-supply unit 34 through the opening H3.

According to this embodiment, the assembly person-hour of the robot control apparatus 10 can be reduced by distributing the cables on the frame 20 in advance. Differences in the wiring route by the operator can be reduced.

The present invention is not limited to the embodiments described above, and many variations are possible without departing from the scope of the present invention. For example, combinations of all or some of the embodiments and variations are also included within the scope of the present invention.

The door provided on the casing 12 is not limited to the door 24 and, instead, may be a sliding door that opens and closes by sliding vertically or horizontally. Instead of the door, a cover may be provided.

When viewed from the side, the frame 20 does not have to be interposed between the internal devices and the door 24. For example, the frame 20 may be disposed further toward the back than the front surface of the internal devices, and the internal devices may protrude from the openings H1 to H6 in the frame 20.

The shape of the frame 20 is not limited to the shapes described in the embodiments. The size of the openings in the frame 20 is not limited so long as the operator is capable of connecting a cable end to a connection port.

The joining parts are not limited so long as they can join the casing 12 and the frame 20. For example, the joining parts may be magnets that join the casing 12 and the frame 20 with a magnetic force.

The control apparatus is not limited to the robot control apparatus. For example, the control apparatus may be for a pump, a machine tool, an elevator, a plant, or a disaster-prevention monitoring system, so long as cables can be connected to internal devices.

A frame that opens and closes together with the door 24 may be further provided, cables may be distributed on this frame so as to connect them to devices secured to the door 24, such as an exhaust fan.

As described above, for the control apparatus according to an embodiment of the present invention, the number of assembly person-hours can be reduced.

What is claimed as new and is desired to be secured by Letters Patent of the United States is:

1. A control apparatus comprising:
a casing;
an internal device accommodated in the casing and having a connection port to be connected to a cable;
a frame on which the cable is distributed, the frame having an opening large enough for an operator to connect an end of the cable to the connection port through the opening; and
a joining part joining the casing and the frame.

2. The control apparatus according to claim 1, wherein the cable is distributed on the frame on a side opposite to the side facing the internal devices.

3. The control apparatus according to claim 1, wherein a mark is applied to the frame at a predetermined position.

4. The control apparatus according to claim 1, wherein
the frame has a cable duct along members of the frame defining the opening, and
the cable is lead through the cable duct.

5. The control apparatus according to claim 1, wherein the frame is disposed to oppose the front surface of the internal device.

6. A method of manufacturing a control apparatus comprising the steps of:
disposing an internal device inside a casing:
distributing a cable along a predetermined position on a frame having an opening;
attaching the frame with the cable on the casing; and
connecting the cable distributed on a side of the frame opposite to the side facing the internal device to a connection port of the internal device through the opening.
